(19) United States
(12) Patent Application Publication
(10) Pub. No.: US 2026/0276684 A1
(43) Pub. Date: Sep. 17, 2026

(54) MICROWAVE POWER DETECTION SYSTEM AND METHOD FOR CONTROLLING CONSISTENCY OF MULTI-CHANNEL MICROWAVE POWER DETECTION

(71) Applicant: HEFEI INSTITUTE OF PHYSICAL SCIENCE, CHINESE ACADEMY OF SCIENCES, Hefei (CN)

(72) Inventors: Liang Zhu, Hefei (CN); Wendong Ma, Hefei (CN); Lianmin Zhao, Hefei (CN); Sheng Liu, Hefei (CN); Yiman Jiang, Hefei (CN); Mao Wang, Hefei (CN); Jiafang Shan, Hefei (CN); Fukun Liu, Hefei (CN)

(21) Appl. No.: 19/396,307

(22) Filed: Nov. 20, 2025

Related U.S. Application Data
(63) Continuation-in-part of application No. PCT/CN2025/110468, filed on Jul. 24, 2025.

(30) Foreign Application Priority Data
Mar. 12, 2025 (CN) 202510287834.3

(51) Int. Cl. G01R 21/133

(52) U.S. Cl. CPC G01R 21/133

(57) ABSTRACT

The present disclosure discloses a microwave power detection system and a method for controlling consistency of multi-channel microwave power detection. The method includes: performing a π-pad attenuation test on a plurality of combinations of resistance values using a π-pad attenuation test circuit unit of the microwave power detection system to determine an initial π-pad attenuation value of branch detection modules, performing the multi-channel microwave power detection based on the initial π-pad attenuation value, then selecting one of the branch detection modules, microwave power detection data of which is closest to an average value of multi-channel microwave power detection data, as a reference circuit, adjusting the branch detection modules other than the reference circuit, and completing consistency setting of the multi-channel microwave power detection. The present disclosure may effectively eliminate differences among the branch detection modules, better control the consistency and improve precision and reliability of the multi-channel microwave power detection.

### CROSS-REFERENCE TO RELATED APPLICATIONS

The present disclosure is a Continuation-In-Part Application of PCT Application No. PCT/CN2025/110468 filed on Jul. 24, 2025, which claims the benefit of Chinese patent application no. 202510287834.3 filed on Mar. 12, 2025, and entitled “Microwave Power Detection System and Method for Controlling Consistency of Multi-Channel Microwave Power Detection”, which is hereby incorporated by reference in its entirety.

### TECHNICAL FIELD

The present disclosure relates to the field of microwave power detection, and in particular to a microwave power detection system and a method for controlling consistency of multi-channel microwave power detection.

### BACKGROUND

With the continuous development of science and technology, the requirements for microwave power detection are increasing, especially in complex systems that require multi-channel high-power microwave power detection.

On one hand, high-power microwave systems often require testing of dozens or even hundreds of channels of microwave signals. However, a high-precision test instrument is only suitable for a test experiment of testing a very small number of channels, making it impossible to use the high-precision test instrument for an acquisition of the dozens or even hundreds of channels of microwave signals. And traditional microwave power detection systems also have significant limitations in terms of detection precision, particularly high-power microwave systems used in high-energy physics and industrial applications are unable to meet the requirements for high-precision detection. On the other hand, in a high-power microwave system, during microwave heating at kilowatt or even megawatt levels, dozens of microwave sources must be used simultaneously for heating. The detection of input power, power losses during transmission, and reflected power of the microwave sources often requires dozens or even hundreds of microwave detection devices. Although actual output microwave power is the same, differences caused by internal inconsistencies in the microwave detection devices increase a workload for subsequent feedback control.

### SUMMARY

An objective of the present disclosure is to provide a microwave power detection system and a method for controlling consistency of multi-channel microwave power detection, thereby improving detection precision and consistency of the multi-channel microwave power detection.

To achieve the above objective, an embodiment of the present disclosure provides a microwave power detection system, including a microwave signal input unit, a power detection unit, a π-pad attenuation test circuit unit, and a signal processing and control unit;
the microwave signal input unit is configured to receive a microwave signal and input the microwave signal into the power detection unit;
the power detection unit includes a plurality of branch detection modules, each of the plurality of the branch detection modules includes a π-pad attenuation circuit, a detection circuit, and an exponential detector, the π-pad attenuation circuit is configured to process the microwave signal input into the power detection unit, the detection circuit is configured to receive the microwave signal processed by the π-pad attenuation circuit, and the exponential detector is configured to process the microwave signal processed by the detection circuit into an electrical signal and output the electrical signal to the signal processing and control unit;
the signal processing and control unit is configured to process and analyze the electrical signal output by the exponential detector to achieve consistency control during the multi-channel microwave power detection; and
the π-pad attenuation test circuit unit is configured to test the π-pad attenuation circuit, to determine an actual attenuation value and a resistance value of the π-pad attenuation circuit.

In an optional embodiment, the π-pad attenuation test circuit unit includes a test circuit board, and the test circuit board includes a to-be-tested π-pad attenuation circuit, a microstrip impedance matching structure, a fixing device, and a test instrument interface;
input and output microstrip impedances of the microstrip impedance matching structure are each 50 ohms;
the fixing device is configured to fix two ends of the test circuit board to a red copper block through a microwave high-frequency connector; and
the test instrument interface is configured to connect a vector network analyzer to test the to-be-tested π-pad attenuation circuit through the vector network analyzer.

In an optional embodiment, the exponential detector is an exponential detector similar to ADL5501.

In an optional embodiment, each of the plurality of the branch detection modules includes a voltage stabilizing circuit, and the voltage stabilizing circuit includes a plurality of multi-operating voltage detection chips; and

Where, each of the plurality of the multi-operating voltage detection chips is designed and mounted using a same batch of chips.

In an optional embodiment, the microwave power detection system is powered by a linear power supply.

In an optional embodiment, a packaging of the to-be-tested π-pad attenuation circuit includes one of 0603, 0402, 0805, and 1206.

To achieve the above objective, an embodiment of the present disclosure further provides a method for controlling consistency of multi-channel microwave power detection, applied to the microwave power detection system as described above, including:
determining a π-pad attenuation value range based on test requirements and a linear region of a detection chip;
selecting a plurality of combinations of the resistance values based on the π-pad attenuation value range, and performing a π-pad attenuation test on the plurality of the combinations of the resistance values using the π-pad attenuation test circuit unit, to determine an initial π-pad attenuation value of the plurality of the branch detection modules;
performing the multi-channel microwave power detection based on the initial π-pad attenuation value to obtain multi-channel microwave power detection data, and selecting one of the plurality of the branch detection modules, microwave power detection data of which is closest to an average value of the multi-channel microwave power detection data, as a reference circuit; and
changing a π-pad attenuation value of each of the plurality of the branch detection modules to adjust the plurality of the branch detection modules other than the reference circuit based on the reference circuit, thereby controlling the consistency of the multi-channel microwave power detection.

In an optional embodiment, the selecting a plurality of combinations of the resistance values based on the π-pad attenuation value range, and performing a-pad attenuation test on the plurality of the combinations of the resistance values using the π-pad attenuation test circuit unit, to determine an initial π-pad attenuation value of the plurality of the branch detection modules, includes:
calculating corresponding two π-pad attenuation resistance values based on the π-pad attenuation value range, selecting at least two resistance values, for each of the two π-pad attenuation resistance values, that are close to the π-pad attenuation resistance values, and combining the selected resistance values in two-by-two combinations to obtain the plurality of the combinations of the resistance values; and
performing the π-pad attenuation test on the plurality of the combinations of the resistance values using the π-pad attenuation test circuit unit to obtain actual attenuation values for the plurality of the combinations of the resistance values, and using a median value of the actual attenuation values as the initial π-pad attenuation value of the plurality of the branch detection modules.

In an optional embodiment, the performing the multi-channel microwave power detection based on the initial π-pad attenuation value to obtain multi-channel microwave power detection data, and selecting one of the plurality of the branch detection modules, microwave power detection data of which is closest to an average value of the multi-channel microwave power detection data, as a reference circuit, includes:
using a single signal source, and within a power output range of the signal source, testing an output voltage data of each of the plurality of the branch detection modules in a step size of 1 dBm, to obtain a plurality of sets of test data corresponding to each of the plurality of the branch detection modules;
performing fitting on the plurality of sets of the test data corresponding to each of the plurality of the branch detection modules to obtain a measured input power-output voltage curve for each of the plurality of the branch detection modules; and
calculating an average curve for the measured input power-output voltage curve for the plurality of the branch detection modules, and selecting one of the plurality of the branch detection modules, the measured input power-output voltage curve of which is closest to the average curve, as the reference circuit.

In an optional embodiment, after the changing a π-pad attenuation value of each of the plurality of the branch detection modules to adjust the plurality of the branch detection modules other than the reference circuit based on the reference circuit, thereby controlling the consistency of the multi-channel microwave power detection, the method further includes:
performing a verification test on the plurality of the branch detection modules to ensure that an acquisition of multi-channel microwave power corresponds to a same input-output formula.

Compared with the prior art, in the microwave power detection system and the method for controlling the consistency of the multi-channel microwave power detection provided by the embodiments of the present disclosure, the microwave power detection system is capable of processing the input microwave signal through the π-pad attenuation circuit, adjusting power of the microwave signal to an appropriate range, ensuring a subsequent normal operation of the detection circuit and the exponential detector, and improving the precision and stability of the detection. Additionally, the π-pad attenuation circuit is further tested through the π-pad attenuation test circuit unit to determine the actual attenuation value and the resistance value thereof, thereby further improving the precision and consistency of the multi-channel microwave power detection. According to the method for controlling consistency of the multi-channel microwave power detection, the π-pad attenuation test is performed on the plurality of the combinations of the resistance values by the π-pad attenuation test circuit unit to determine the initial π-pad attenuation value of the plurality of the branch detection modules, thereby providing accurate basic data for subsequent power detection and reducing a detection error caused by an inaccurate π-pad attenuation value; one of the plurality of the branch detection modules with the microwave power detection data closest to the average value of the multi-channel microwave power detection data is selected as the reference circuit; and other branch detection modules of the plurality of the branch detection modules are adjusted based on the reference circuit, so that differences among the plurality of the branch detection modules may be effectively eliminated, the consistency of the multi-channel microwave power detection may be better controlled, a detection result of each channel may be closer to an actual value, and the precision and reliability of the multi-channel microwave power detection may be further improved.

### BRIEF DESCRIPTION OF THE DRAWINGS

To more clearly illustrate the technical solutions of the present disclosure, the accompanying drawings to be used in the embodiments will be briefly described below. It is evident that the accompanying drawings in the following description are merely some embodiments of the present disclosure. For those skilled in the art, other drawings may be derived from these accompanying drawings without creative efforts.

FIG. 1 is a structural block diagram of a microwave power detection system according to an embodiment of the present disclosure;

FIG. 2 is a schematic diagram of a π-pad attenuation circuit according to an embodiment of the present disclosure;

FIG. 3 is a flowchart of a method for controlling consistency of multi-channel microwave power detection according to an embodiment of the present disclosure.

### DETAILED DESCRIPTION

The following description will be provided with reference to the accompanying drawings of the embodiments of the present disclosure to clearly and completely describe the technical solutions of the embodiments of the present disclosure. It should be noted that the described embodiments are merely some rather than all of the embodiments of the present disclosure. All other embodiments obtained by a person of ordinary skill in the art without creative efforts based on the embodiments of the present disclosure shall fall within the scope of protection of the present disclosure.

It should be noted that when an element is referred to as being “connected to” another element, it may be directly connected to the other element or indirectly connected to the other element. It should be understood that the term “connection” in the following embodiments should be understood as “electrical connection”, “communication connection”, etc., if the circuits, modules, units, etc. being connected are capable of transmitting electrical signals or data to each other. Furthermore, the terms “first” and “second” are used only for descriptive purposes and should not be understood as indicating or implying relative importance or implicitly indicating the number of indicated technical features. Thus, features defined with “first” or “second” may explicitly or implicitly include one or more of the features. The limitation “at least one” refers to one or more, and the limitation “a plurality of” refers to two or more.

The simplest implementation of microwave power detection is to detect through a detection circuit composed of a detector diode and an auxiliary circuit. However, with the development of semiconductor technology, the detector diode and the auxiliary circuit have been integrated into a single detection chip, so that the detection function can be achieved more conveniently. At the same time, there are many off-the-shelf power acquisition devices that may directly read power values through certain software, further simplifying microwave power detection. Microwave power detection precision is a core indicator for microwave detection devices. For simple microwave heating experiments or industrial microwave drying and freezing applications, microwave power precision does not need to be very high, and meeting basic requirements is sufficient. However, for applications such as high-energy physics and microwave coating, which require precision control at a W (watt) level, higher precision is demanded. The reference to “W level” means that fluctuation or deviation of power must be controlled within the order of magnitude of watts (e.g., allowable error ranges may be ±1 W, etc., depending on specific requirements). For example, during a process of diamond synthesis through a microwave plasma method, a power fluctuation range must not exceed 10 W when the microwave power is constant; otherwise, quality of the diamond coating will be significantly affected. For microwave systems with a power level of several tens of kilowatts, a fluctuation of no more than 10 W is equivalent to giving strict requirements on a stability of the microwave source and also presents significant challenges for the power detection system.

Currently, there are some high-precision microwave power detection instruments, such as U2000 series of Agilent Technologies Inc., offer high measurement precision and fully meet the precision requirements. However, these detection instruments are expensive and bulky, and are suitable for detecting one or two microwave sources in a laboratory. These detection instruments become prohibitively costly and cumbersome for a high-power microwave system including a plurality of (and in some cases dozens of) microwave sources. Here, the high-power microwave (HPM) refers to a microwave signal with a high energy density and a large power output, primarily composed of radio waves within a frequency range from 300 MHz to 300 GHz. The high-precision microwave power detection instruments are only suitable for detecting a few channels of the microwave power. For the system including the plurality of microwave sources, such as a 10 MW microwave heating system in the Experimental Advanced Superconducting Tokamak (EAST) device for artificial sun nuclear fusion, which includes several hundred kilowatts of solid-state microwave sources requiring a synthesis of dozens of microwave channels, in these high-power microwave systems, detecting of dozens or even hundreds of microwave signals is required. Using commercial high-precision detection instruments for such a large number of microwave signals is clearly inappropriate, as the commercial high-precision detection instruments are only suitable for experiments involving a very small number of channels, and are unsuitable for the high-power microwave systems in high-energy physics and industrial applications.

In an existing high-power microwave system, a large number of microwave sources and the need for power detection at each stage of a power amplifier often require dozens or even hundreds of power detection. Here, the limitation “each stage of the power amplifier” refers to a circuit unit at each stage in a multi-stage amplification structure of the power amplifier (abbreviated as “PA”). Currently, online detection is primarily used, that is, reflected and incident power are generated through microstrip coupling. A basic coupling circuit may be designed in an early stage using professional simulation software. In this way, effective precision is ensured during low-power (generally <10 W) detection. However, when designing online detection for power levels in tens or hundreds of watts, results obtained from the professional simulation software when the professional simulation software designs high-power microwave circuits may only provide a general guidance, and a simulation value may differ significantly from a theoretical value, requiring actual adjustments. In a high-power microwave state, precision of the online detection is influenced by numerous factors such as cavity material, cavity height, and shielded cavity dimensions, making it difficult to ensure the precision. In addition, in the high-power microwave systems, during microwave heating at kilowatt or even megawatt levels, dozens of microwave sources must be used simultaneously for heating. The detection of input power, power losses during transmission, and reflected power of the microwave sources often requires dozens or even hundreds of microwave detection devices. Although actual output microwave power is the same, differences caused by internal inconsistencies in the microwave detection devices increase a workload for subsequent feedback control. Therefore, how to improve consistency of power detection in the high-power microwave system is also a prominent problem.

Based on the above-mentioned problems existing in the prior art, embodiments of the present disclosure, in conjunction with the accompanying drawings, provide a microwave power detection system and a method for controlling consistency of multi-channel microwave power detection, which will be described in detail below.

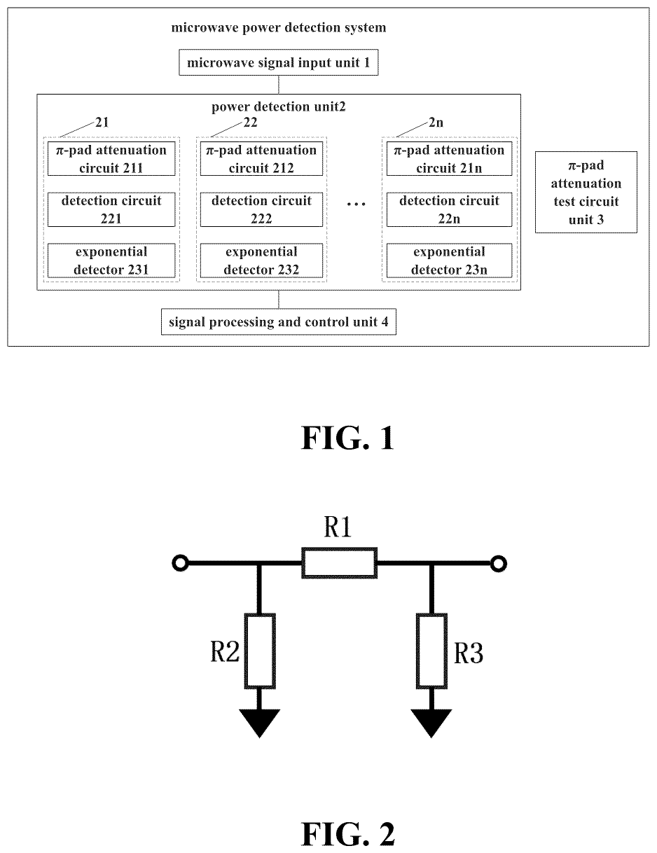

Referring to FIG. 1, FIG. 1 is a structural block diagram of a microwave power detection system according to an embodiment of the present disclosure. As shown in FIG. 1, the microwave power detection system includes a microwave signal input unit 1, a power detection unit 2, a π-pad attenuation test circuit unit 3, a signal processing and control unit 4, and a processor, where the processor is configured to execute a program unit stored in a memory, i.e., the signal processing and control unit 4.

The microwave signal input unit 1 is configured to receive a microwave signal and input the microwave signal into the power detection unit 2.

Here, the microwave signal input unit 1 includes a signal receiving component, such as a receiving port/coupler, which serves as an “entrance” for the microwave signal to enter the microwave signal input unit 1; the microwave signal input unit 1 further includes a signal output transmission component, such as a transmission line and a connector, which transmits the preprocessed microwave signal to the power detection unit 2 through a coaxial cable, a microstrip line, etc.

The power detection unit 2 includes a plurality of branch detection modules 21 to 2n (n is an integer ≥2), each of the plurality of the branch detection modules 2N (where N is an integer from 1 to n) includes a π-pad attenuation circuit 21n, a detection circuit 22n, and an exponential detector 23n; the π-pad attenuation circuit is configured to process the input microwave signal, the detection circuit is configured to receive and process the microwave signal processed by the π-pad attenuation circuit, and the exponential detector is configured to process the microwave signal processed by the detection circuit into an electrical signal and output the electrical signal to the signal processing and control unit.

The signal processing and control unit 4 is configured to process and analyze the electrical signal output by the exponential detector to achieve consistency control during multi-channel microwave power detection.

The π-pad attenuation test circuit unit 3 is configured to test the π-pad attenuation circuit, to determine an actual attenuation value and a resistance value of the π-pad attenuation circuit.

For example, the system includes the microwave signal input unit, the power detection unit, the π-pad attenuation test circuit unit, and the signal processing and control unit. The microwave signal input unit is connected to an external microwave source to introduce the microwave signal into the system; the power detection unit includes n branch detection modules responsible for performing power detection on the microwave signal; the π-pad attenuation test circuit unit is configured to precisely measure parameters of the π-pad attenuation circuit before multi-channel microwave power detection is performed; and the signal processing and control unit analyzes and processes detection data to achieve consistency control of multi-channel microwave power detection.

It should be noted that in traditional microwave power detection systems, logarithmic detectors are commonly used. However, a change in detection voltage of the logarithmic detector corresponds to a large power difference, resulting in an unstable output detection voltage. During microwave power detection, changes of such large power difference cause the output detection voltage to fluctuate significantly. Additionally, a direction of change of an output power of most logarithmic detectors differs from that of an input power, making it difficult for an operator to intuitively understand and analyze detection results during actual operation and data processing.

In this regard, in embodiments of the present disclosure, in order to increase smoothness of power detection, the logarithmic detector such as AD8319 is no longer selected, but the exponential detector is used instead of the logarithmic detector. Because the power difference corresponding to a change in detection voltage of the exponential detector is much smaller, resulting in a more stable output detection voltage, which is extremely advantageous for subsequent control operations, and may significantly reduce a workload for consistency control. Additionally, compared to the logarithmic detector, response values of the exponential detector can better follow the positive logic, which facilitates the operator to quickly understand power changes represented by detection data, and is more advantageous in both data processing and system control.

In an optional embodiment, an operating frequency range of the exponential detector is 50 MHz to 6 GHz.

It should be noted that ADL5501 is an average-responding power detector suitable for measuring a high crest factor signal, with an operating frequency range from 50 MHz to 6 GHz and excellent temperature stability within a 30 dB range. Therefore, when dealing with complex modern communication waveforms, the exponential detector with a same or similar operating frequency range (e.g., 49 MHz to 6 GHz) as the ADL5501 may accurately measure power, cover a wider frequency range, maintain relatively stable performance at different environmental temperatures, ensure precision and reliability of measurement results, and reduce an influence of temperature on system performance.

It should be noted that, in general, resistances required by the π-pad attenuation circuit is calculated based on an attenuation value of a required microwave signal amplitude. As shown in FIG. 2, the π-pad attenuation circuit includes three resistors: R1, R2, and R3. Here, R2 and R3 are connected between an input terminal and ground, and between an output terminal and ground, respectively, R1 is connected between the input terminal and the output terminal, and a circuit of π-pad is formed. Based on the principle of resistive voltage division, when a signal passes through the π-pad attenuation circuit, the input signal first passes through the series resistor R1, R1 applies a certain voltage division effect to the signal, reducing a voltage of the signal. The signal then passes through the parallel resistor R2, where part of the signal is shunted to ground, further reducing an amplitude of the signal output. Finally, the signal passes through another series resistor R3 and is again subjected to voltage division, thereby achieving attenuation of the amplitude of the signal. By appropriately selecting resistance values of the three resistors, precise control of the attenuation of the amplitude of the signal may be achieved.

For example, to achieve an attenuation value of 11 dB, according to calculations, a recommended resistance value of the series resistor R1 is 81.66 ohms, and recommended resistance values of the two ground resistors R2 and R3 are both 89.24 ohms, ant the three resistors form the π-pad attenuation circuit to achieve the attenuation value of 11 dB. However, standard resistors with a resistance value of 89.24 ohms are not readily available on the market, typically, resistors with resistance values such as 89 ohms, 90.9 ohms, or 91 ohms, which are close to the resistance value of 89.24 ohms, can be found on the market. Additionally, resistors with higher precision tend to be more expensive. Moreover, an actual attenuation value achieved by a π-pad attenuation resistor typically differs from a theoretically calculated attenuation value by 0.1-0.3 dB. For a detection of low-power microwave systems at levels of several tens of watts, such differences are insignificant, but for a detection of high-power microwave systems at levels of several kilowatts or megawatts, such differences are unacceptable. Therefore, to improve detection precision, it is essential to determine the actual attenuation value achieved by the π-pad attenuation circuit rather than adjusting the signal based on the theoretically calculated attenuation value.

Additionally, π-pad attenuation measurements are typically performed online, that is, during a real-time measurement, the π-pad attenuation circuit is primarily measured using a probe or a lead. However, results of such measurement may vary due to differences in an angle of the probe or lead, or a quality of soldering of the probe or lead.

Therefore, in view of the above problems in the prior art, an embodiment of the present disclosure provides a π-pad attenuation test circuit unit specifically designed for the π-pad attenuation circuit to accurately test the actual attenuation value thereof.

In an optional embodiment, the π-pad attenuation test circuit unit includes a test circuit board, the test circuit board includes a to-be-tested π-pad attenuation circuit, a microstrip impedance matching structure, a fixing device, and a test instrument interface.

The microstrip impedance matching structure includes an input port microstrip line, an output port microstrip line, and a matching network, where the input port microstrip line and the output port microstrip line are each a 50-ohm standard microstrip line; and the matching network may be a λ/4 impedance transformer, a T-match/π-match network, or a stepped-impedance matching network.

Input and output microstrip impedances of the microstrip impedance matching structure are each 50 ohms;

The fixing device, such as a red copper block, is configured to fix two ends of the test circuit board to the red copper block through a microwave high-frequency connector. Here, the microwave high-frequency connector is a connector with an operating frequency not less than 3 MHz, for example, an SMA (SubMiniature version A) connector or an N-type connector.

The test instrument interface is configured to connect a vector network analyzer to test the to-be-tested π-pad attenuation circuit through the vector network analyzer. Here, the test instrument interface is a microwave high-frequency connector, for example, a SMA connector.

It can be understood that an intermediate circuit of the test circuit board is the to-be-tested π-pad attenuation circuit. According to the test circuit board, the input and output microstrip impedances are designed to standard 50 ohms, and the test circuit board is fixed to the red copper block, with two ends thereof fixed using the microwave high-frequency connector (for example, the SMA connector). Then, a π-pad attenuation test is performed on the to-be-tested π-pad attenuation circuit after the vector network analyzer is connected with the test circuit board.

When performing multi-channel microwave power detection, appropriate resistors may be selected in advance based on a required attenuation value and then combined to obtain combinations of the resistors, and then actual attenuation values of these combinations of the resistors are then obtained through test using the π-pad attenuation test circuit unit. Then, one combination of the resistors of the combinations of the resistors, an actual attenuation value of which equals to a median value of the actual attenuation values, is selected to be uniformly soldered to form the π-pad attenuation circuits in the n branch detection modules. Compared to conventional online measurements, a result of such multi-channel microwave power detection is the most accurate, and the attenuation value of the π-pad attenuation circuit is not affected by differences in the probe or soldering length of the lead.

Specifically, a packaging of the to-be-tested π-pad attenuation circuit may be 0603, but is not limited to 0603; it may also be 0402/0805/1206, etc. Specifically, the packaging of 0402 belongs to a type of smaller packaging with minimal space requirements, while the packaging of 0603 has a moderate size, balancing power handling capacity and space requirements. Compared to the packaging of 0402, the packaging of 0603 may bear higher power, have greater current carrying capacity and heat dissipation performance, and may not occupy excessive space on the circuit board. The packaging of 0805 has a relatively larger volume, providing higher power handling capability, greater current carrying capacity, and better heat dissipation performance. The packaging of 1206 is the largest in size among these packagings, featuring strong power handling capacity and current processing capability, capability of withstanding significant power loss, and good heat dissipation performance. The packagings of 0805 and 1206 may bear higher power, however, as frequency increases, parasitic parameters thereof become larger, phase noise and greater signal loss at high frequencies (>1 GHz) are easily introduced. In specific implementation, an appropriate packaging type may be selected based on power and frequency requirements.

In an optional embodiment, each of the plurality of the branch detection modules is provided with a voltage stabilizing circuit, and the voltage stabilizing circuit includes a plurality of multi-operating voltage detection chips.

Here, each of the plurality of the multi-operating voltage detection chips is designed and mounted using a same batch of chips, i.e., the same batch of chips is used and mounted through a same process.

In an optional embodiment, the microwave power detection system is powered by a linear power supply.

It is worth noting that, in actual testing, it is found that power supply ripple has a great influence on a detection output voltage. Therefore, when performing the multi-channel microwave power detection, it is recommended to use a unified power supply and the linear power supply with smaller power supply ripple, which helps to minimize interference noise introduced by a switching power supply. Additionally, in the microwave power detection system, to further avoid a fluctuation of the detection output voltage caused by the interference noise of the power supply, the voltage stabilizing circuit may be used again in each of the plurality of the branch detection modules, which helps reduce the fluctuation of the detection output voltage to the lowest, thereby further improving measurement precision and consistency of the detection.

Based on the above implementation embodiments of the system, an embodiment of the present disclosure provides a method for controlling consistency of multi-channel microwave power detection to further improve precision and consistency of the multi-channel microwave power detection.

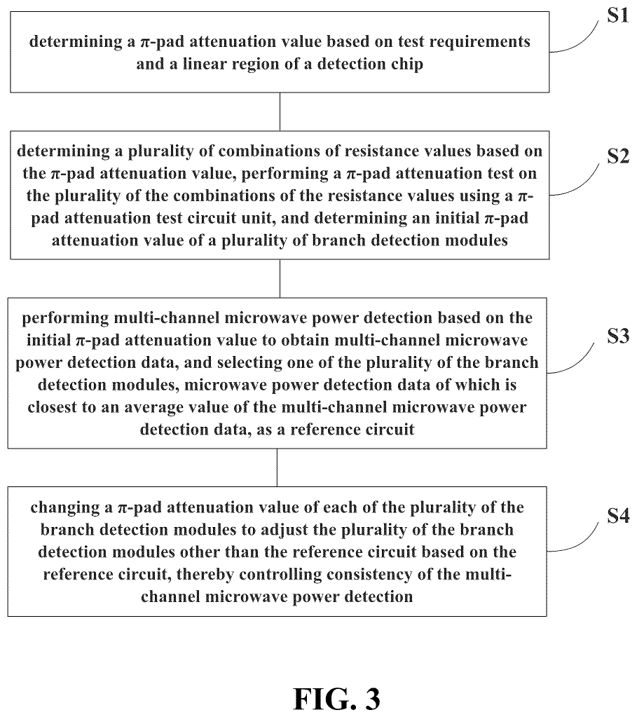

Referring to FIG. 3, FIG. 3 is a flowchart of the method for controlling the consistency of the multi-channel microwave power detection according to the embodiment of the present disclosure. As shown in FIG. 3, the method for controlling the consistency of the multi-channel microwave power detection includes steps S1 to S4:

S1: determining a π-pad attenuation value range based on test requirements and a linear region of a detection chip.

The π-pad attenuation value range is determined based on the test requirements and set in conjunction with the linear region of the detection chip, ensuring an operating point of the detection chip is positioned at an appropriate position within the linear region of the detection chip (preferably a middle section of the linear region of the detection chip), which guarantees an accuracy and consistency of detection results.

The test requirements refer to that, given varying effective power input ranges and linear regions (as detailed in respective datasheets of different detection chips) of the different detection chips, a test needs to ensure that measured power of the detection chip, after being attenuated by the π-pad attenuation value, falls within the linear region thereof.

It can be understood that the π-pad attenuation value range needs to first be determined, which may be determined based on the test requirements of the system and the linear region of the detection chip. For example, if it is necessary to simultaneously acquire power of multi channels of 1 kW (60 dBm, i.e., 60 decibel milliwatts), with a coupler coupling factor of 40 dB and the selected detection chip of ADL5501, an output power is linear within a power input range from −25 dBm to 10 dBm.

For a 1 kW power amplifier, it is desirable to detect output power from 0 to 1 kW during testing. However, an actual output power of the 1 kW power amplifier may be higher, so a maximum power level detected during actual detection is 1.25 KW (61 dBm), thereby determining the actual detection range to be between 0 dBm (1 mW) and 61 dBm. For input power ranging from 0 dBm (1 mW) to 61 dBm, after coupling through the coupler with the coupling factor of 40 dB, the coupled power ranges from −40 dBm to 21 dBm. For high-power measurement, a power precision of 20 dBm (0.1 W) is already quite high in industrial applications, so focus should be on a range from −20 dBm to 21 dBm. Then according to a power linear range of the selected detection chip (i.e., the linear region of the detection chip) from −25 dBm to 10 dBm (i.e., the purpose is to attenuate a signal from −20 dBm to 21 dBm into the power linear range of from −25 dBm to 10 dBm of the detection chip through the π-pad attenuation circuit), in the most extreme case, a signal of 21 dBm needs to be attenuated to about 10 dBm. Therefore, it is necessary to provide a signal attenuation value of 21 dB-10 dB=11 dB (the difference between 21 dBm and 10 dBm represents a relative change in power, and therefore, the unit of the difference is dB), which allows to determine that a π-pad attenuation value is about 11 dB.

S2: determining a plurality of combinations of the resistance values based on the π-pad attenuation value range, and performing a π-pad attenuation test on the plurality of the combinations of the resistance values using the π-pad attenuation test circuit unit, to determine an initial π-pad attenuation value of the plurality of the branch detection modules;

In an optional embodiment, the selecting a plurality of combinations of the resistance values based on the π-pad attenuation value range, and performing a π-pad attenuation test on the plurality of the combinations of the resistance values using the π-pad attenuation test circuit unit, to determine an initial π-pad attenuation value of the plurality of the branch detection modules, includes:
calculating corresponding two-pad attenuation resistance values based on the π-pad attenuation value range, selecting at least two resistance values, for each of the two π-pad attenuation resistance values, that are close to the π-pad attenuation resistance values, and combining the selected resistance values in two-by-two combinations to obtain the plurality of the combinations of the resistance values, where the resistance values that are close to the π-pad attenuation resistance values, refer to the resistance values, within ±3 ohms of a theoretical resistance value, of standard resistors, and the theoretical resistance value is the resistance value calculated according to the π-pad attenuation value; and
performing the π-pad attenuation test on the plurality of the combinations of the resistance values using the π-pad attenuation test circuit unit to obtain actual attenuation values of the plurality of the combinations of the resistance values, and using a median value of the actual attenuation values as the initial π-pad attenuation value of the plurality of the branch detection modules.

It should be understood that most of resistance values of the π-pad attenuation resistors are not integral values. Some of the π-pad attenuation resistors with non-integral resistance values are rarely available on the market or are extremely expensive. For the non-conventional resistance values (i.e., the theoretical resistance value), in an embodiment of the present disclosure, resistors with non-integral resistance values closer to the non-conventional resistance values are preferably selected. For example, to achieve the π-pad attenuation value of 11 dB, it is generally recommended to use resistors with resistance values of 89.24 ohms and 81.66 ohms, but in practice, such resistors with the resistance values are virtually nonexistent. However, resistors with integral resistance values such as 91 ohms or 82 ohms are commonly available and suitable for mass production. But, after tested by the π-pad attenuation test circuit unit of the embodiment of the present disclosure, the actual attenuation value for the combination of the resistance values of 91 ohms and 82 ohms is only 10.73 dB. Therefore, in the embodiment of the present disclosure, it is continuous to select resistors with resistance values close to the non-conventional resistance value from the market for fine-tuning. For example, in addition to the commonly available resistors with resistance values of 82 ohms and 91 ohms, other resistors with resistance values such as 86.6 ohms and 88.7 ohms are also relatively easy to obtain from the market, and prices thereof are cheaper and lead times thereof are shorter compared to else resistors.

Therefore, in the embodiment of the present disclosure, four resistance values of 82 ohms, 86.6 ohms, 88.7 ohms, and 91 ohms are selected. And after the four resistance values are combined in two-by-two combinations, there are a total of 16 combinations, as shown in Table 1 below, the π-pad attenuation circuit includes 3 resistors with 2 different resistance values. By means of the π-pad attenuation test circuit unit of the embodiment of the present disclosure, attenuation values for the 16 combinations are measured by the vector network analyzer, and characteristic impedances thereof are measured. Referring to Table 1, Table 1 lists actual attenuation values and impedances corresponding to the π-pad attenuation circuit of each of combinations of the resistance values according to the embodiment of the present disclosure.

TABLE 1
Actual attenuation values and impedances corresponding to the π-pad
attenuation circuit of each of combinations of the resistance values

| | Resistance | Resistance | Actual | Actual |
|---|---|---|---|---|
| | value of R1 | value of R2 | Impedance | Attenuation |
| Serial No. | (Ω) | and R3 (Ω) | (Ω) | Value (dB) |
| 1 | 91 | 82 | 56 | 11.67 |
| 2 | 91 | 86.6 | 58.4 | 11.45 |
| 3 | 91 | 88.7 | 59.9 | 11.33 |
| 4 | 91 | 91 | 60.9 | 11.20 |
| 5 | 88.7 | 82 | 56.4 | 11.53 |
| 6 | 88.7 | 86.6 | 58.5 | 11.34 |
| 7 | 88.7 | 88.7 | 59.8 | 11.20 |
| 8 | 88.7 | 91 | 60.6 | 11.09 |
| 9 | 86.6 | 82 | 55.8 | 11.39 |
| 10 | 86.6 | 86.6 | 58.7 | 11.20 |
| 11 | 86.6 | 88.7 | 59.5 | 11.07 |
| 12 | 86.6 | 91 | 60.5 | 10.97 |
| 13 | 82 | 82 | 55 | 11.18 |
| 14 | 82 | 86.6 | 58.2 | 10.96 |
| 15 | 82 | 88.7 | 58.9 | 10.83 |
| 16 | 82 | 91 | 60 | 10.73 |

As shown in Table 1, based on the actual attenuation values for the 16 combinations of the resistance values, an average value of the actual attenuation values is 11.196, the actual attenuation value closest to the average value is 11.20, but 11.20 corresponds to three different combinations of the resistance values and three different impedances. Compared to a single combination of the resistance values, there are more uncertainties, so the actual attenuation value of 11.18 (i.e., the median value of 11.18) is selected as a reference. The resistance values of three π-pad attenuation resistors corresponding to the actual attenuation value of 11.18 are all 82 ohms. Therefore, in the embodiment of the present disclosure, the three resistors each possessing the resistance value of 82 ohms are configured to form the π-pad attenuation circuit in each of the plurality of the branch detection modules, and 11.18 dB is used as the initial π-pad attenuation value of each of the plurality of the branch detection modules. Initially, all n branch detection modules use the same initial π-pad attenuation value.

It should be noted that, in microwave circuits, an impedance of the π-pad attenuation circuit should ideally be consistent with the impedance of the microstrip line, which is typically 50 ohms. However, actual impedances will inevitably differ from theoretical resistance values. As shown in Table 1, the actual impedances are all greater than 50 ohms, with the maximum impedance being 60.9 ohms; and the minimum actual attenuation value is 10.73 dB, and the maximum actual attenuation value is 11.67 dB. In practical applications such as the multi-channel microwave power detection, a plurality of π-pad attenuation circuits are required to process signals from different channels. However, the plurality of π-pad attenuation circuits possess different impedances and attenuation values due to different selected resistance values. Actual data (i.e., actual data in Table 1) obtained from this test may be used in subsequent work, in combination with the test data in Table 1, to adjust these π-pad attenuation circuits, ensuring their performance (such as impedance matching and attenuation amount) is more consistent. For example, by fine-tuning the resistance values or using other compensation measures, the plurality of π-pad attenuation circuits may achieve similar performance in practical applications, thereby improving the consistency and accuracy of the entire multi-channel microwave power detection system. Therefore, these test data are also prepared for consistency adjustment of subsequent multi-channel microwave power detection.

It should be noted that, the π-pad attenuation test used in the embodiments of the present disclosure is not only applicable to the consistency adjustment of the multi-channel microwave power detection in the embodiments of the present disclosure, but may also be applied to other microwave circuits where the π-pad attenuation circuits are used for isolation, pre-attenuation, and other applications.

S3: performing the multi-channel microwave power detection based on the initial π-pad attenuation value to obtain multi-channel microwave power detection data, and selecting one of the plurality of the branch detection modules, microwave power detection data of which is closest to an average value, as a reference circuit.

After determining the initial π-pad attenuation value, all n branch detection modules use the same initial π-pad attenuation value in their detection.

In an optional embodiment, the performing the multi-channel microwave power detection based on the initial π-pad attenuation value to obtain multi-channel microwave power detection data, and selecting one of the plurality of the branch detection modules, microwave power detection data of which is closest to an average value of the multi-channel microwave power detection data, as a reference circuit, includes:
using a single signal source, and within a power output range of the signal source, testing an output voltage data of each of the plurality of the branch detection modules in a step size of 1 dBm, to obtain a plurality of sets of test data corresponding to each of the plurality of the branch detection modules, here, the step size refers to an interval value between two input power values, and the test data includes an input power value, and an output voltage data corresponding to each of the plurality of the branch detection modules after the input power value is input;
performing fitting on the plurality of sets of the test data corresponding to each of the plurality of the branch detection modules to obtain a measured input power-output voltage curve for each of the plurality of the branch detection modules; and
calculating an average curve for the measured input power-output voltage curve for all of the plurality of the branch detection modules, and selecting one of the plurality of the branch detection modules, the measured input power-output voltage curve of which is closest to the average curve, as the reference circuit. Here, the average curve refers to: when an input power is a certain value (e.g., −25 dBm), all output voltages of the n branch detection modules corresponding to the input power are averaged to an average output voltage; and so on, the average output voltages of the n branch detection modules are calculated for all standard input power, so as to obtain a relationship curve between the input power and the average output voltages for the n branch detection modules, i.e., the average curve.

For example, when the n branch detection modules are tested, the single signal source is used as a test source, a test range is from −20 dBm (the lowest output power value of the signal source used) to 25 dBm (the highest output power value of the signal source used), and the step size is 1 dBm. The output voltage data of the n branch detection modules are tested and recorded, and input power data and the output voltage data of the n branch detection modules are fitted. The detection chip is powered by the internal voltage stabilizing circuit of the branch detection module, a theoretical output voltage of the internal voltage stabilizing circuit is 3.3V, however, test data shows that an actual output voltage range is 3.1-3.35V, additionally, due to an influence of precision of the π-pad attenuation resistors, the input power-output voltage curves are different, which is understandable. A highest output voltage value and a lowest output voltage value may be removed from the test data for each branch detection module, and then an average value are calculated for each branch detection module. One of the n branch detection modules, the test data of which is closest to the average value may be selected as a reference. In practice, each of the plurality of the branch detection modules is tested from −20 dBm (the lowest output power value of the signal source used) to 25 dBm (the highest output power value of the signal source used), yielding 45 data. The n branch detection modules are all tested, yielding a total of n*45 data. After removing the highest and lowest output voltage values obtained at each power level for each of the n branch detection modules, the average value is taken. One of the plurality of the branch detection modules with the measured input power-output voltage curve closest to the average curve is selected as the reference circuit at the power level. Here, the test range is from −20 dBm to 25 dBm and the step size is 1 dBm, that is, a first power level is −20 dBm, a next power level is increased by 1 dBm, and 25 dBm is a last power level.

S4. changing a π-pad attenuation value of each of the plurality of the branch detection modules to adjust the plurality of the branch detection modules other than the reference circuit based on the reference circuit, thereby controlling the consistency of the multi-channel microwave power detection.

In an optional embodiment, after the changing a π-pad attenuation value of each of the plurality of the branch detection modules to adjust the plurality of the branch detection modules other than the reference circuit based on the reference circuit, thereby controlling the consistency of the multi-channel microwave power detection, the method further includes:
performing a verification test on the plurality of the branch detection modules to ensure that an acquisition of multi-channel microwave power corresponds to a same input-output formula.

Specifically, based on the reference circuit, n−1 branch detection modules of the n branch detection modules other than the reference circuit are respectively adjusted. The adjustment is primarily achieved by changing the π-pad attenuation value, that is why the median value is selected as the initial π-pad attenuation value, which is convenient for subsequent fine-tuning. In addition, after adjustment, the n−1 branch detection modules are subjected to actual testing to check whether the input power-output voltage curve of each of the n−1 branch detection modules are kept consistent with the reference curve (the input power-output voltage curve of the reference circuit). And finally, after completing the adjustment of the n−1 branch detection modules, the verification test is performed on the n branch detection modules again, then test results for the n branch detection modules are compared to analyze the consistency of the entire multi-channel microwave power detection system, and complete consistency setting. After the input power-output voltage curves of the n−1 branch detection modules are kept consistent with the reference curve (the input power-output voltage curve of the reference circuit) and the consistency setting is completed, working characteristics of acquisition channels of the n branch detection modules may be described using the same input-output formula. That is, regardless of which channel, given a same input microwave power signal, a corresponding output detection result may be calculated using the same input-output formula. This has the advantage that, during system design and data processing, there is no need to establish complex, different mathematical models and calculation methods for various channels, significantly simplifying theoretical architecture and actual operational processes of the system.

In summary, in the microwave power detection system and the method for controlling the consistency of the multi-channel microwave power detection provided by the embodiments of the present disclosure, the microwave power detection system achieves a complete process from microwave signal input to final power detection result output through an orderly cooperation of the microwave signal input unit, the power detection unit, the π-pad attenuation test circuit unit, and the signal processing and control unit. Each unit has a clear division of work, ensuring the precision and reliability of the microwave power detection. Here, the power detection unit includes the plurality of the branch detection modules, enabling simultaneous detection of multi-channel microwave signals, meeting a requirement for power detection of the multi-channel microwave signals in practical applications and improving detection efficiency and system practicality. Furthermore, the input microwave signal may be processed through the π-pad attenuation circuit, and power of the microwave signal may be adjusted to an appropriate range to ensure a subsequent normal operation of the detection circuit and the exponential detector, thereby improving the precision and stability of the detection. Additionally, the π-pad attenuation circuit is tested by the π-pad attenuation test circuit unit to determine the actual attenuation value and the resistance value thereof, thereby further improving the precision and consistency of the multi-channel microwave power detection.

The method for controlling the consistency of the multi-channel microwave power detection first determines the π-pad attenuation value range based on the test requirements and the linear region of the detection chip, ensuring that the microwave signal is processed within the linear region of the detection chip to avoid distortion or error caused by the microwave signal exceeding the linear region, thereby improving the accuracy of the power detection; by performing the π-pad attenuation test on the plurality of the combinations of the resistance values by the π-pad attenuation test circuit unit, the initial π-pad attenuation value of the plurality of the branch detection modules is determined, thereby providing accurate basic data for subsequent power detection and reducing a detection error caused by an inaccurate π-pad attenuation value; and one of the plurality of the branch detection modules with the microwave power test data closest to the average value of the multi-channel microwave power test data is selected as the reference circuit, and other branch detection modules of the plurality of the branch detection modules are adjusted based on the reference circuit, so that differences among the plurality of the branch detection modules may be effectively eliminated, which better controls the consistency of the multi-channel microwave power detection, makes the detection result of each channel closer to an actual value, and further improves the accuracy and reliability of the multi-channel microwave power detection.

The above are preferred embodiments of the present disclosure. It should be pointed out that, for those of ordinary skill in the art, several improvements and modifications can be made without departing from the principle of the present disclosure, and these improvements and modifications are also considered to be within the scope of protection of the present disclosure.

1. A method for controlling consistency of multi-channel microwave power detection, applied to a microwave power detection system, the microwave power detection system comprising:
a microwave signal input unit, a power detection unit, a π-pad attenuation test circuit unit, and a signal processing and control unit; wherein
the microwave signal input unit is configured to receive a microwave signal and input the microwave signal into the power detection unit;
the power detection unit comprises a plurality of branch detection modules, each of the plurality of the branch detection modules comprises a «-pad attenuation circuit, a detection circuit, and an exponential detector, the π-pad attenuation circuit is configured to process the microwave signal input into the power detection unit, the detection circuit is configured to receive the microwave signal processed by the π-pad attenuation circuit, and the exponential detector is configured to process the microwave signal processed by the detection circuit into an electrical signal and output the electrical signal to the signal processing and control unit;
the signal processing and control unit is configured to process and analyze the electrical signal output by the exponential detector to achieve consistency control during the multi-channel microwave power detection; and
the π-pad attenuation test circuit unit is configured to test the π-pad attenuation circuit, to determine an actual attenuation value and a resistance value of the π-pad attenuation circuit;
wherein the method for controlling the consistency of the multi-channel microwave power detection comprises:
determining a π-pad attenuation value range based on test requirements and a linear region of a detection chip;
determining a plurality of combinations of the resistance values based on the π-pad attenuation value range, and performing a π-pad attenuation test on the plurality of the combinations of the resistance values using the π-pad attenuation test circuit unit, to determine an initial π-pad attenuation value of the plurality of the branch detection modules;
performing the multi-channel microwave power detection based on the initial π-pad attenuation value to obtain multi-channel microwave power detection data, and selecting one of the plurality of the branch detection modules, microwave power detection data of which is closest to an average value of the multi-channel microwave power detection data, as a reference circuit; and
changing a π-pad attenuation value of each of the plurality of the branch detection modules to adjust the plurality of the branch detection modules other than the reference circuit based on the reference circuit, thereby controlling the consistency of the multi-channel microwave power detection.

2. The method for controlling the consistency of the multi-channel microwave power detection according to claim 1, wherein the determining a plurality of combinations of the resistance values based on the π-pad attenuation value range, and performing a π-pad attenuation test on the plurality of the combinations of the resistance values using the π-pad attenuation test circuit unit to determine an initial π-pad attenuation value of the plurality of the branch detection modules, comprises:
calculating corresponding two π-pad attenuation resistance values based on the π-pad attenuation value range, selecting at least two resistance values, for each of the two π-pad attenuation resistance values, that are close to the π-pad attenuation resistance values, and combining the selected resistance values in two-by-two combinations to obtain the plurality of the combinations of the resistance values; and
performing the π-pad attenuation test on the plurality of the combinations of the resistance values using the π-pad attenuation test circuit unit to obtain actual attenuation values for the plurality of the combinations of the resistance values, and using a median value of the actual attenuation values as the initial π-pad attenuation value of the plurality of the branch detection modules.

3. The method for controlling the consistency of the multi-channel microwave power detection according to claim 1, wherein the performing the multi-channel microwave power detection based on the initial π-pad attenuation value to obtain multi-channel microwave power detection data, and selecting one of the plurality of the branch detection modules, microwave power detection data of which is closest to an average value of the multi-channel microwave power detection data, as a reference circuit, comprises:
using a single signal source, and within a power output range of the signal source, testing an output voltage data of each of the plurality of the branch detection modules in a step size of 1 dBm, to obtain a plurality of sets of test data corresponding to each of the plurality of the branch detection modules;
performing fitting on the plurality of sets of the test data corresponding to each of the plurality of the branch detection modules to obtain a measured input power-output voltage curve for each of the plurality of the branch detection modules; and
calculating an average curve for the measured input power-output voltage curve for the plurality of the branch detection modules, and selecting one of the plurality of the branch detection modules, the measured input power-output voltage curve of which is closest to the average curve, as the reference circuit.

4. The method for controlling the consistency of the multi-channel microwave power detection according to claim 1, wherein, after the changing a π-pad attenuation value of each of the plurality of the branch detection modules to adjust the plurality of the branch detection modules other than the reference circuit based on the reference circuit, thereby controlling the consistency of the multi-channel microwave power detection, the method further comprises:
performing a verification test on the plurality of the branch detection modules to ensure that an acquisition of multi-channel microwave power corresponds to a same input-output formula.

5. The method for controlling the consistency of the multi-channel microwave power detection according to claim 1, wherein the π-pad attenuation test circuit unit comprises a test circuit board, the test circuit board comprises a to-be-tested π-pad attenuation circuit, a microstrip impedance matching structure, a fixing device, and a test instrument interface;
input and output microstrip impedances of the microstrip impedance matching structure are each 50 ohms;
the fixing device is configured to fix two ends of the test circuit board to a red copper block through a microwave high-frequency connector; and
the test instrument interface is configured to connect a vector network analyzer to test the to-be-tested π-pad attenuation circuit through the vector network analyzer.

6. The method for controlling the consistency of the multi-channel microwave power detection according to claim 1, wherein an operating frequency range of the exponential detector is 50 MHz to 6 GHz.

7. The method for controlling the consistency of the multi-channel microwave power detection according to claim 1, wherein each of the plurality of the branch detection modules comprises a voltage stabilizing circuit, and the voltage stabilizing circuit comprises a plurality of multi-operating voltage detection chips;
wherein each of the plurality of the multi-operating voltage detection chips is designed and mounted using a same batch of chips.

8. The method for controlling the consistency of the multi-channel microwave power detection according to claim 5, wherein the microwave power detection system is powered by a linear power supply.

9. The method for controlling the consistency of the multi-channel microwave power detection according to claim 5, wherein a packaging of the to-be-tested π-pad attenuation circuit comprises one of 0603, 0402, 0805, and 1206.
